(19) United States
(12) Patent Application Publication
(10) Pub. No.: US 2001/0007373 A1
(43) Pub. Date: Jul. 12, 2001

(54) Tape carrier for semiconductor device and method of producing same

(76) Inventors: Yoshinori Kadota, Tokyo (JP); Yutaka Furukawa, Tokyo (JP); Yoshiki Sota, Osaka (JP); Hiroyuki Juso, Osaka (JP)

Correspondence Address: HELFGOTT & KARAS, P.C., 60th FLOOR, EMPIRE STATE BUILDING, NEW YORK, NY, 10118, US

(21) Appl. No.: 09/754,836

(22) Filed: Jan. 4, 2001

(30) Foreign Application Priority Data
Jan. 12, 2000 (JP) 2000-3495

(51) Int. Cl. H01L 29/40; H01L 21/44; H01L 23/48; H01L 23/52

(52) U.S. Cl. 257/730; 257/737; 438/613

(57) ABSTRACT

A tape carrier for a semiconductor device comprising a flexible insulation tape having via holes for a solder ball, a metal wiring layer formed on one surface of the insulation tape, the via halls for the solder balls having an opening on the other surface of the insulating tape, and a metal brace formed on the periphery of the opening of the respective via holes, wherein the metal brace is formed in a ring-shape provided with a cutout opening having a width up to 4% of the circumferential length of the periphery, or comprises a plurality of arcuate shape portions, such that gaps are simetorically provided and positioned between the arcuate shape portions,, and that the total width of the gaps is up to 40% of the circumferential length of the periphery, and wherein the metal braces have a surface to which Ni plating is applied, and Au plating is applied to the Ni plating.

### BACKGROUND OF THE INVENTION

1. Technical Field of the Invention

The present invention relates to a semiconductor device, and particularly to a BGA (Ball Grid Array) package tape carrier, or a CSP (Chip Scall Package) tape carrier used for the semiconductor device.

2. Description of the Prior Art

Recently, with the high performance and small size of electronic equipment represented for example by personal computers, there is the requirement for densification and miniaturization of the semiconductor package also. Corresponding to the densification and miniaturization of a semiconductor package, there is the advent of semiconductor packages of area array type such as BGA packages or CSPs which are able to correspond even more to multiple terminals, than the conventional peripheral type semiconductor packages represented by QFP (Quad Flat Package).

Presently, with BGA packages and CSPs, plastic BGAs using a printed wiring board for the base material is predominant.

However, as a BGA package and CSP having virtues for example that narrow pitch inner lead bonding to the connection with the semiconductor chip is possible, that a Reel to Reel process can be used in the manufacture, and that low cost is possible, tape BGA and tape CSP which uses a resin film being non conductive and having flexibility for the base material, is continuing to increase.

In the tape carrier material for the tape BGA or tape CSP, an insulation tape such as a polyamide film laminated with a copper foil is used. Here, mainly used is one which is constructed with a metal wiring layer connected to the semiconductor tape on one surface of the tape carrier, and a mounting portion for solder balls for substrate connection on the other face.

In such a construction, for conduction between the metal wiring layer side and the solder ball side and for solder ball mounting, via holes are necessary in the insulation tape. As a method of forming via holes, there is known a method where holes are formed with a dry process laser method, or where wet process etching is used. In order to form the desired via holes, a desired metal mask is formed by photoetching, after which dry type laser or wet type etching is carried out. Then, in order for good wetting of the solder on the metal surface of the metal wiring layer exposed from the aperture portions, Ni plating and Au plating is applied. After this, solder balls are mounted on the aperture portions, so that the semiconductor device is produced. By means of the solder balls, the semiconductor device is connected to the printed wiring board and other parts.

However, in the case where a semiconductor device of the above construction is installed on a printed wiring board or the like, there are the following problems.

In the semiconductor device, since the coefficient of thermal expansion of the printed wiring board and the semiconductor chip connected to the tape carrier are different, then due to repetitive changes in the ambient temperature, stresses concentrate at the connection portions between the metal wiring layer of the semiconductor device and the solder balls. In particular, in the via holes, cracks occur in the area to the solder ball parts from the part where the Ni under-plating and Au plating therein are applied to the conducting portion on the metal wiring layer side, so that faults arise.

With respect to this problem, JP Patent Publication Toku Kai Hei 11-251471 discloses a technology to form a ring-shaped reinforcing pattern located at the position of the solder ball on the rear surface of the tape and in contact with the solder ball.

The problem of cracking is substantially solved by the invention in JP Patent Publication Toku Kai Hei 11-2514711. However, there are some cases where cracks are still caused, and any improvements are required. It is thought that this cracks are caused by gases concentrated in the via hall.

### SUMMARY OF THE INVENTION

Therefore, it is an object of the present invention to provide a tape carrier and manufacturing method thereof, where the aforementioned cracks do not occur, and a semiconductor device and manufacturing method therefor which uses this tape carrier.

Another object of the present invention is to provide a tape carrier and a manufacturing method therefor for solving the above mentioned problems, and a semiconductor device and manufacturing method therefor which uses this tape carrier.

### BRIEF DESCRIPTION OF THE DRAWINGS

FIG. 1 is a cross sectional view of one example of the tape carrier for semiconductor device according to the present invention.

FIG. 2 is a cross sectional view of one example of the semiconductor device according to the present invention.

FIG. 3 is an enlarged cross sectional view of part of the semiconductor device of FIG. 2.

FIG. 4 is a plan view of a circular metal brace with a cutout.

FIG. 5 is a plan view of a circular metal brace with two paths for gas removal.

FIG. 6 is a plan view of a circular metal brace with three paths for gas removal.

FIG. 7 is a plan view of a circular metal brace with four paths for gas removal.

FIG. 8 is a plan view of a triangular metal brace with a cut out.

FIG. 9 is a plan view of a rectangular metal brace with a cutout.

FIG. 10 is a plan view of a pentagonal with a cutout.

FIG. 11 is a plan view of a triangular metal brace with a gas removal path in a straight portion.

FIG. 12 is a plan view of a rectangular metal brace with a gas removal path in a straight portion.

FIG. 13 is a plan view of a triangular metal brace with a gas removal path in a straight portion.

FIG. 14 is a plan view of a triangular metal brace with a gas removal path in a corner portion.

FIG. 15 is a plan view of a rectangular metal brace with a gas removal path in a corner portion.

FIG. 16 is a plan view of a pentagonal metal brace with a gas removal path in a corner portion.

FIG. 17 is a cross sectional view of part of an insulation tape on which a metal foil and photoresist are arranged thereon.

FIG. 18 is a cross sectional view of part of a tape member on which a metal wiring layer is arranged.

FIG. 19 is a cross sectional view of part of a tape member on which via holes are arranged.

FIG. 20 is a cross sectional view of part of a tape member on which photoresist is coated.

FIG. 21 is a cross sectional view of part of a tape member on which metal braces are arranged.

FIG. 22 is a cross sectional view of part of the tape carrier for semiconductor device.

### DETAILED DESCRIPTION OF THE PREFERRED EMBODIMENTS

With the semiconductor device tape carrier of the present invention, a metal wiring layer is formed on one face of an insulation tape having flexibility, and metal braces are formed on part of the periphery of the solder ball via holes which open to the other face. The metal brace may be made ring shape, and a cutout opening of a width equal to or less than 4% of the circumferential length provided, or the metal brace may be made in two or more arcuate shape portions, so that gaps are simetorically provided and positioned, and the total width of the gaps is equal to or less than 40% of the circumferential length.

Ni plating is applied to the surface of the metal braces and Au plating is applied to the Ni plating, or only Au plating is applied to the surface of the metal braces.

The manufacturing method for the semiconductor device tape carrier of the present invention involves the steps of; forming a metal foil on both surfaces of the insulation tape having flexibility, forming a protective film and then etching and removing the protective film, so that a metal wiring layer for mounting semiconductor chips is formed on one of the surfaces, and that the insulation tape is exposed at desired positions on the other surface, protecting the surface including the metal wiring layer with a protective film of resin, performing etching on the exposed portion of the insulation tape to form via holes at the desired portions, forming a resin protective film on the via holes and part of the periphery of the via holes, and removing said metal foil at the portion exposed from the protective film by etching, and the remaining portion of the metal foil forms a metal brace, and then removing the protective film formed on both surfaces of the insulation tape.

The metal brace can be made in a ring-shape having a cutout with a width up to 4% of the circumferential length of the periphery, or the metal brace may comprise a plurality of arcuate shape portions, such that gaps are simetorically provided and positioned between the arcuate shape portions, and that the total width of the gaps is up to 40% of the circumferential length of the periphery.

Furthermore, Ni plating is applied to the surface of the metal brace and then Au plating is applied, or only Au plating is applied to the surface of the metal brace.

With the semiconductor device of the present invention, semiconductor chips are connected to the metal wiring layer using the semiconductor device tape carrier, and the solder balls are mounted so as to cover the via holes and the metal brace. Part of the solder ball enters the via hall through fusion to form a column portion for electrically connecting the solder ball to the metal wiring layer.

With the manufacturing method for a semiconductor device of the present invention, in addition to the manufacturing method for the semiconductor device tape carrier, this involves connecting a semiconductor chip to the metal wiring layer, and mounting solder balls so as to cover the via holes and the metal foil portion adjacent to the via holes.

Hereunder is a detailed description of embodiments, referring to the drawings, of a tape carrier and manufacturing method therefor of the present invention, and a semiconductor device which uses the tape carrier and a manufacturing method therefor.

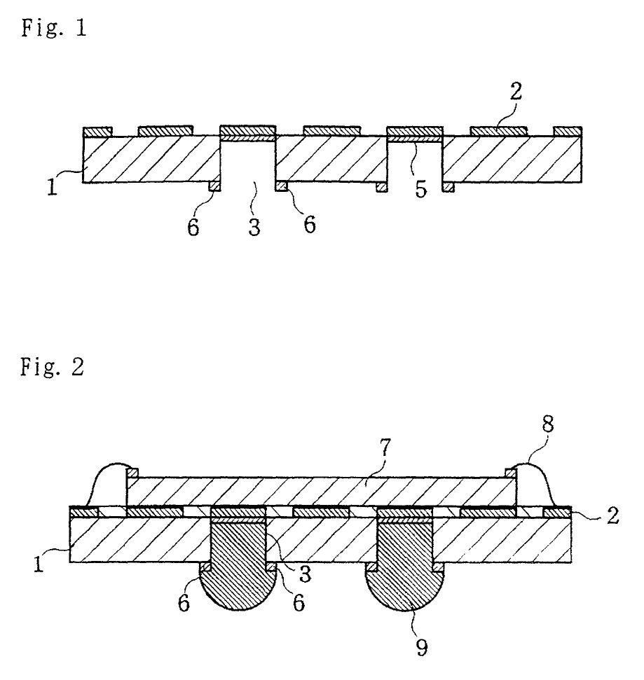

FIG. 1 is a cross section showing an embodiment of a semiconductor device tape carrier of the present invention.

An insulation tape 1 is used and made, for example, from a polyamide film having flexibility. The thickness of the insulation tape 1 is around several ten microns. A metal wiring layer 2 is formed on one surface (front surface) of the insulation tape 1. On the other surface (rear surface) is formed via holes 3 for conduction with the insulation wiring layer 2 and for mounting solder balls. The size of the via holes 3 is made different depending on the size of the semiconductor device, and the diameter at the opening portion is from several ten to several hundred microns. In the formation of these via holes 3, there is a method involving dry laser or wet etching. In order to ensure good wettability of the solder at the contact portion between the metal wiring layer 2 and the solder balls in the via hole 3, Ni plating is applied as required, and Au plating is applied thereon to form a plating layer 5. Then, corresponding to each one of the via holes 3, a metal brace 6 is provided for mounting reinforcement of the solder balls, at the periphery of the via holes 3. At the surface of the metal brace 6, in order to ensure good wettability of the solder balls, Au plating with the Ni under-plating, or Au plating only is applied as required. Thus, the tape carrier for semiconductor device of the present invention is constructed.

FIG. 2 is a cross section showing an embodiment of a semiconductor device of the present invention.

A semiconductor chip 7 is connected to the front surface, that is to the side of the metal wiring layer 2, of the tape carrier for semiconductor device. In the bonding of the semiconductor chip 7, an adhesive is used. A sheet form adhesive may be attached to the top of the semiconductor device tape carrier, or a liquid adhesive may be applied. The semiconductor chip 7 and the metal wiring layer 2 are connected by wire bonding 8. Then, solder balls 9 are mounted on the rear surface of the tape carrier. By this, the solder balls 9 are reinforced with the metal brace 6. Thus, the construction of the semiconductor device of the present invention is constructed.

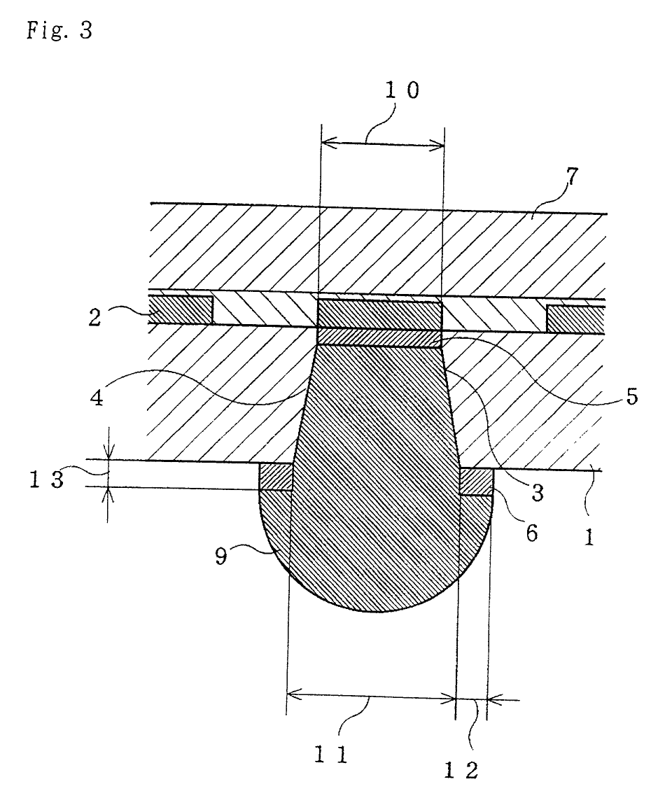

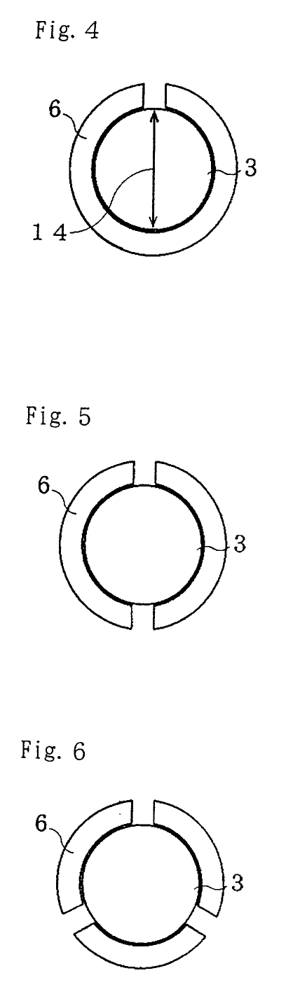

Next in the construction of the metal brace 6 according to the present invention, for example FIG. 3 is a cross section showing a ring-shaped metal brace 6 provided at the periphery of via holes 3 of the semiconductor device tape carrier, and solder balls 9 mounted. FIG. 4 is a plan view of the metal brace 6.

The solder balls 9 are mounted on the via holes 3 of the tape carrier for semiconductor device using a reflow method. The reflow method is conducted such that a predetermined amount of solder previously is supplied to a connection portion, which is then heated at a desired temperature by way of radiation, conduction or convection to melt the solder for bonding. At this time, in order to ensure good wettability of the solder, Ni plating is applied to the metal wiring layer 2 inside the via holes 3, and Au plating is applied thereon to thereby form a plating layer 5. After this the solder balls 9 are mounted.

Here, the shape of the via holes 3 differs depending on the method of forming the via holes, and in particular with a wet etching such as with polyamide etching, then as shown in FIG. 3, the via holes 3 are of a shape to form a taper. Due to this taper, the diameter 10 of the upper portion of the via holes is less than the diameter 11 of the opening portion. The smaller the diameter 10 of the upper portion of the via holes, the narrower can be the gap between the electrode sections in the semiconductor chip 7 and the metal wiring layer on the rear surface, enabling densification of the metal wiring layer 2 and miniaturization of the semiconductor chip 7.

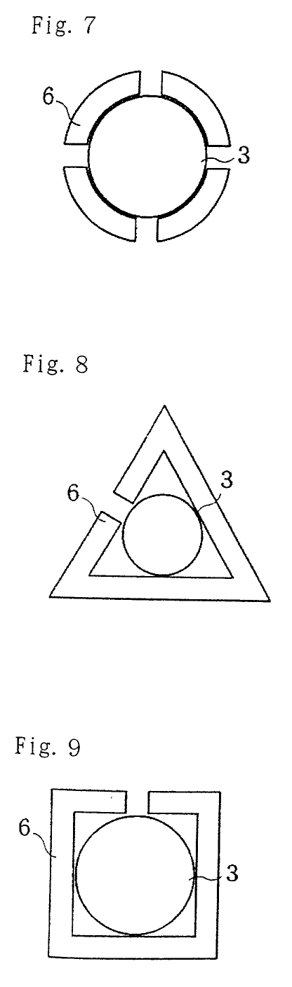

In order to prevent cracks and breakage, the metal brace 6 is provided on the boundary between the solder balls and the via holes for reinforcing. Furthermore, for example as shown in FIG. 4, cutouts for gas removal may be provided in the metal brace 6, or as shown in FIG. 5 through FIG. 7, the metal brace 6 may be made as two or more portions of arcuate shape, with a plurality of gas removal paths provided and formed on the periphery of the via holes. Otherwise, when this is mounted on the printed circuit board, a stress concentration would occur in the connecting portion between the aforementioned Au plating with the Ni under-plating and the solder ball, due to repetitive changing of the ambient temperature, causing cracks and breakage. When the solder balls 9 are mounted on the via holes 3, a gap occurs due to repetitive changes in ambient temperature, at the side wall portion 4 of the via holes 3 so that gas of for example bubbles can easily accumulate.

The width of the cutouts is preferably less than 4% of the circumferential length. If the width of the cutout openings is large, the solder balls are no longer formed in a circular shape, so that the center deviates from the via hole, and connection cannot be accurately made to the printed wiring board.

Furthermore, the plurality of gas removal paths are symmetrically provided, and the total width is equal to or less than 40% with respect to the circumferential length. If the total width of the paths exceeds 40%, the reinforcing effect with the solder balls cannot be expected.

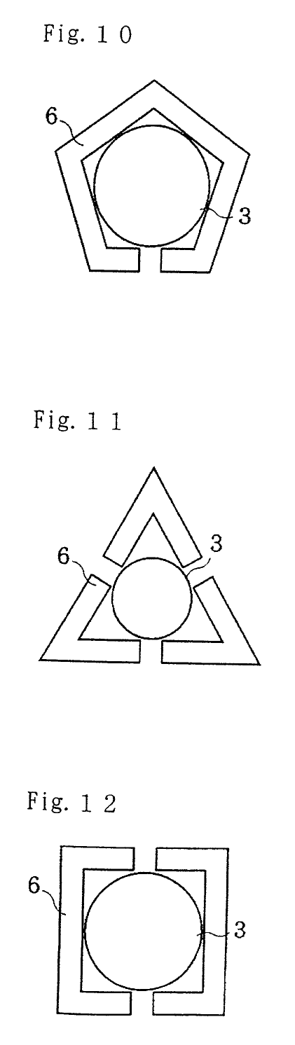

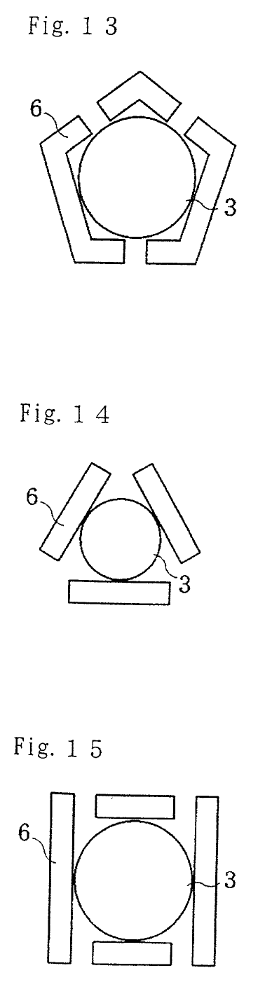

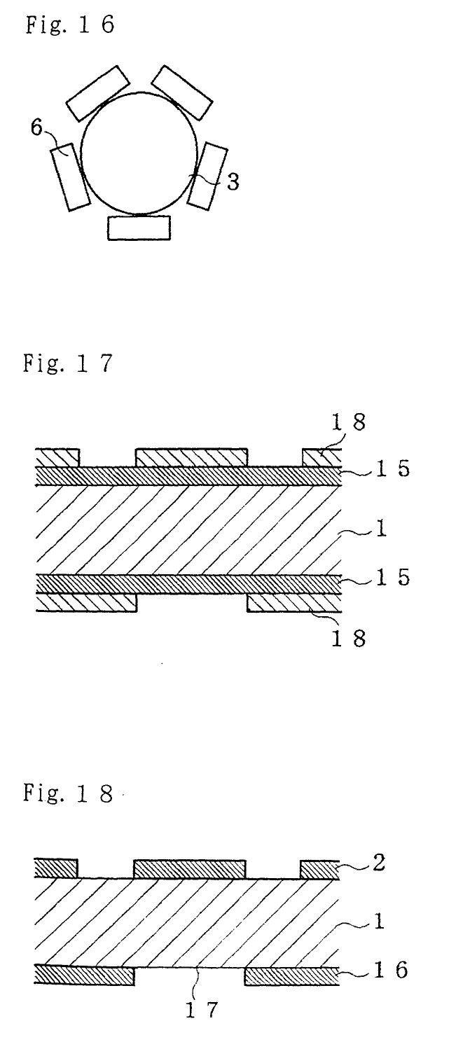

The shape of the metal brace 6 is not limited to ring shape provided this can enclose the via holes 3 and reinforce so that the mounted solder balls 9 do not flow out. As shown for example in FIG. 8 through FIG. 16, this may be formed in a polygon shape. Also in the shape of the polygon, as shown in FIG. 8 through FIG. 10, cutout openings for gas removal may be included, or as shown in FIG. 11 through FIG. 16, this may be divided into two or more parts (preferably at symmetrical positions), so that a plurality of gas removal paths are provided.

As shown in FIG. 3, the width 12 of the metal brace 6 may be made large to the extent that there are no cracks or disconnection of the mounted solder balls 9, and 10 μm or more is preferably. If the width 12 is less than 10 μm, this becomes too narrow, and the adhesion strength of the insulation tape 1 becomes weak, so that during the manufacturing process of the tape carrier for semiconductor device, the metal brace 6 peels or drops off. Furthermore, concerning the thickness 13 of the metal brace 6, since the material for forming the metal brace 6 functions as the etching mask for the via hole formation, it is necessary that the thickness is also for functioning as the etching mask. The thickness 13 of the metal brace 6 is preferably around 1 μm to 30 μm. If thinner than 1 μm, the strength for reinforcing the solder ball 9 is weak, so that there is a high possibility of the occurrence of cracks or breakage of the connection portion between the solder ball 9 and the via hole 3. Furthermore, the effect as an etching mask is lost. On the other hand, if the thickness 13 of the metal brace 6 is greater than 30 μm, the removal time of the etching mask and the amount of etching fluid used is increased, and hence the cost for the etching process is increased.

As shown in FIG. 4, for the internal diameter 14 of the metal brace 6, a size is desirable, so that the periphery of the via holes 3 is enclosed by the metal brace 6, that the solder balls 9 can be properly mounted onto and reinforced by the metal brace 6 (around several ten to several hundred microns).

The material of the metal brace 6 is the metal foil used in the etching mask for forming the via holes. Normally Cu (copper) is used.

Next FIG. 17 through FIG. 22 show a manufacturing method for a tape carrier for semiconductor device of the present invention.

As shown in FIG. 17, a photoetching method is performed on the tape material to which the metal foil 15 is attached on both sides of the insulation tape 1 having flexibility. As shown in FIG. 18, a metal wiring layer 2 for connecting to the semiconductor chip is formed on one face, and an etching mask 16 is formed on the face of the other side at predetermined positions for forming the via holes 3. Formation of the etching mask 16 is by a photoetching method where the face is protected by photoresist 18 so that only the metal foil 15 of the via hole portions is removed, and the insulation tape portion 17 is exposed, and the other portions are masked by the metal foil. Then, etching for performing exposure processing is carried out. In the case where copper is used for the etching mask 16, a cupric chloride solution or a ferric chloride solution is used for the etching solution.

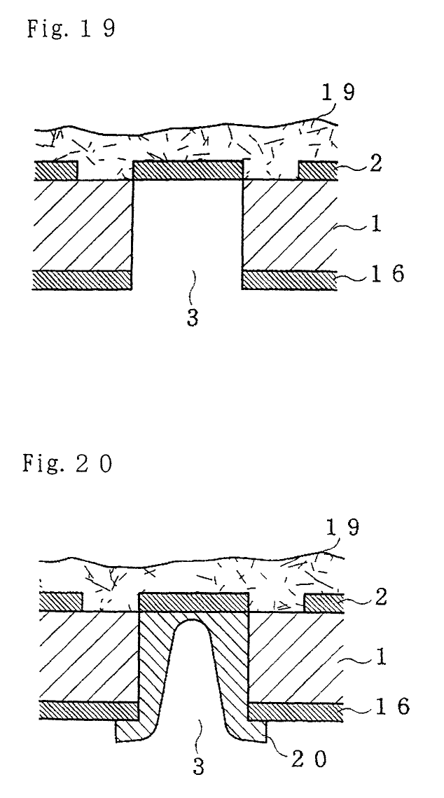

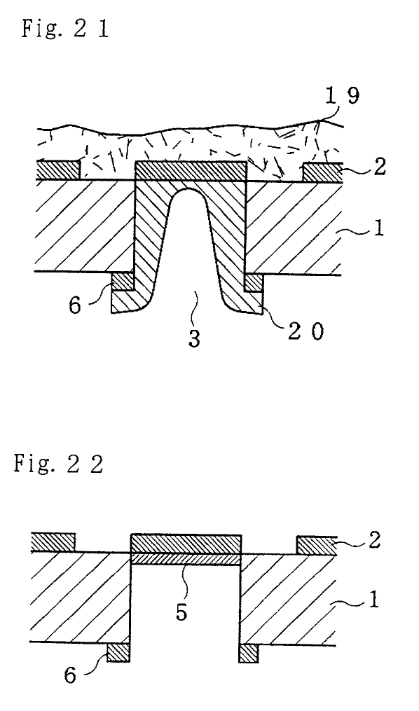

In the formation of the via holes 3 shown in FIG. 19, the exposed portion 17 of the insulation tape outside of the portion which is masked by the etching mask 16, is formed by processing with a photoetching method. At this time, in order to prevent etching on the surface where the metal wiring layer 2 is formed, the surface is protected with resist 19. In the case where polyamide is used for the insulation tape 1, an alkaline etching solution of a non hydrazine group is used for the etching solution. A commercial alkali proof resist is used for the resist 19. As shown in FIG. 19, after forming the via holes 3, then as shown in FIG. 20, these are coated with a photoresist 20 to give a ring shape on top of the etching mask 16 for the periphery of the via holes 3. The etching mask 16 which is not covered with the photoresist 20 is removed by photoetching. Then, the exposure process, and the photoetching process are performed, and thereby with the metal foil used in the etching mask 16, as shown in FIG. 21, the metal brace 6 for reinforcing the solder ball is formed on the periphery of the via holes 3. Then, the resist 19 which protects the metal wiring layer 2, and the photoresist 20 remaining on the rear surface are removed with a dilute alcohol solution.

Next, plating is applied to the tape carrier for semiconductor device. At this time, this is plated by either an electroplating method or an electroless plating method.

With the electroplating plating, Ni plating is applied to a portion of the via hole opening portion for conducting to the metal wiring, on the rear face of the metal wiring layer of the tape carrier for semiconductor device, and Au plating is applied over this to give the plating layer 5 (refer to FIG. 22). Prior to this plating, the portion of the metal brace 6 is not electrically connected to the metal wiring layer 2 of the front face. However at the time of Au electroplating, this is coated with a substituted Au in the Au plating bath, and is electrically connected to the metal wiring layer 2. Specifically, upon electric Au plating, the coating is made by the Au which is placed through substitution at the site where the metal composing the metal brace 6 is located, and the Au coating is electrically connected to the metal wiring layer 2. Specifically, the electric Ni plating is conducted on the surface of the metal brace 6, the Ni ion on the surface is replaced by the Au ion in the solution, and the Au is precipitated on the Ni plating for coating.

When the material of the metal brace 6 is copper, the copper ion on the surface of the metal brace 6 is substituted with the Au ion in the plating bath, so that the Au is precipitated on the Cu for coating.

With the electroless plating, Ni plating is applied to a portion of the via hole opening portion for conducting to the metal wiring, on the rear face of the metal wiring layer of the tape carrier for semiconductor device, and Au plating is applied over this to give the plating layer 5 (refer to FIG. 22). On the surface of the portion for the metal brace 6, as mentioned before Ni plating is applied, and Au plating is applied over this. As a result, the portion of the metal brace 6 is electrically connected to the metal wiring layer 2.

Preferably the thickness of the Ni plating is from 1 μm to 8 μm. If this is thinner than 1 μm, the wettability of the solder is poor, while if thicker than 8 μm, the time for plating and the amount of Ni plating used is increased, so that the cost for the plating process is increased. Furthermore, also with the thickness of the Au plating, if this is too thick, the amount of Au plating used is increased so that cost is increased. Therefore a thickness of less than 1 μm is preferable (the thickness of the substitute Au plating at the time of electroplating is less than 0.05 μm).

Above was the manufacturing method for a tape carrier for semiconductor device of the present invention.

As follows is the manufacturing method for a semiconductor device according to the present invention. After manufacturing the tape carrier for semiconductor device by the above mentioned manufacturing method, as shown in FIG. 2, the semiconductor chip 7 is incorporated and packaged. With the bonding of the semiconductor chip 7, a sheet like adhesive having electrical insulation may be affixed at a predetermined position on the semiconductor device tape carrier to effect bonding, or the chip may be mounted by applying a liquid adhesive.

Next, the terminals of the semiconductor chip 7, and the inner lead pad of the metal wiring layer 2 in the tape carrier for semiconductor device, are wire bonded for example by fine gold wires 8. After this, in order to hermetically seal the semiconductor chip 7, the semiconductor chip side may be resin sealed with a commercial epoxy mould resin (not shown in the figure).

Then, the solder balls 9 are connected to the via holes 3 on the rear face, by reflowing. At this time, flux may be used in addition to solder.

Above was the manufacturing method for a semiconductor device of the present invention.

### WORKING EXAMPLES, AND COMPARATIVE EXAMPLES

Some examples of the invention are shown hereunder.

The examples are concerned with a semiconductor device tape carrier and a semiconductor device, corresponding to where the size of the semiconductor chip is 8 mm square, the number of terminals is 64, and the terminal pitch is 0.8 mm.

A tape material was prepared with two sheets of copper foil of 18 μm thickness integrally formed on opposite sides of an insulation tape comprising a polyamide film of 50 μm thickness. This tape material was Espaflex (trade name), with a polyamide (trade name APICAL) of Kanegafuchi Chemical Industries as the base.

The semiconductor device tape carrier was made by a process involving a reel to reel process as described hereunder.

In this working example, a copper wiring layer was formed by a photoetching technique, on the side for connecting the semiconductor chip of the tape carrier for semiconductor device. The wiring pattern of this copper wiring layer was a wiring pattern from an inner lead bonding wire portion provided on four perimeters for connecting the terminals of the semiconductor chip by wire bonding, towards solder ball land electrodes provided in an area array shape facing the interior.

The via holes of the polyamide film for mounting the solder balls were made by etching with an alkaline etching solution in the non hydrazine group (Tore Engineering Company, TPE-3000group). The etching at this time was performed with a method where the etching solution was sprayed from an opposite side to the copper wiring layer, and the copper foil on the rear face is used as the etching mask. That is, the copper foil of only the via hole forming portion on the rear face of the tape carrier was removed by the photoetching, to thereby expose the polyamide film of that portion. Then, after protecting the copper wiring of the front face of the tape carrier with a resist, in a condition with the other portions masked by the copper foil, etching of the polyamide film was performed to thereby open the via holes. A taper was formed divergent toward the rear surface in the via holes.

In this working example, by making the diameter of the copper mask 0.41 mm, via holes were opened with the diameter on the copper wiring side of 0.35 mm. After this, the copper mask was removed using a cupric chloride solution. At this time, resist coating for protecting the copper wiring layer was applied, and a photoresist which differed respectively for the following working examples, and comparative examples, was applied to the rear face.

For the comparative examples 1 and 2, printing was conducted to leave not only the via holes but also ring-shaped copper patterns (hereunder referred to as copper rings) on the via hole surroundings so as to leave a width of 10 μm. No cut out is formed in the copper rings.

For the working example 1, printing was conducted to leave not only the via holes but also copper rings on the via hole surroundings with a width of 10 μm. Moreover, a cutout of 20 μm width was made at one place on the copper ring (FIG. 4).

For the working example 2, printing was conducted to leave not only the via holes but also copper rings on the via hole surroundings with a width of 10 μm. Moreover, a cutout of 20 μm width was made at two places on the copper ring (FIG. 5).

For the comparative examples 3 and 4, printing was conducted to leave not only the via holes but also copper rings on the via hole surroundings with a width of 20 μm.

For the working examples 3 and 4, printing was conducted to leave not only the via holes but also copper rings on the via hole surroundings with a width of 20 μm. Moreover, a cutout of 20 μm width at one or two places, was made on each of the copper rings.

For the comparative examples 5 and 6, printing was conducted to leave not only the via holes but also copper rings on the via hole surroundings with a width of 30 μm.

For the working examples 5 and 6, printing was conducted to leave not only the via holes but also copper rings on the via hole surroundings with a width of 30 μm. Moreover, a cutout of 20 μm width at one or two places, was made on each of the copper rings.

For comparative examples 7 and 8, printing was conducted such that only the opened via holes were filled with photoresist (no ring is formed).

For the comparative examples 9 and 10, printing was conducted to leave not only the via holes but also copper rings on the via hole surroundings with a width of 5 μm.

For the comparative examples 11 and 12, printing was conducted to leave not only the via holes but also copper rings on the via hole surroundings with a width of 5 μm. Moreover, a cutout of 20 μm width at one or two places, was made on each of the copper rings.

In all cases, the copper mask was removed by copper etching to form the copper rings. Then, the protective resist on the front face and the photoresist remaining on the rear face were removed by a dilute alcohol solution.

In the working examples 1, 3 and 5, and the comparative examples 1, 3, 5, 7, 9 and 11, electroplating was performed on the copper wiring layer of the semiconductor tape carrier and on the copper ring of the via hole periphery.

For working examples 2, 4 and 6, and comparative examples 2, 4, 6, 8, 10 and 12, electroless plating was performed.

At this time, the thickness of the Ni plating was 5 μm, and the thickness of the Au plating was 0.2 μm. Furthermore, the thickness of the substitute metal plating for the copper ring in the electroplating was less than 0.05 μm.

After making the semiconductor device tape carrier by the above mentioned process, the semiconductor chips were incorporated to make up the semiconductor device. These were then evaluated after packaging was made on the printed wiring board. With this evaluation, as a reliability evaluation for the connections between the semiconductor device and the printed wiring board, a temperature cycling test was performed.

In assembling the semiconductor device, at first the semiconductor chip was attached and bonded to the central portion of the tape carrier with an epoxy system adhesive having electrical insulation. Then, after wire bonding is conducted between the terminals of the semiconductor chip and the inner lead pads of the metal wiring layer with fine gold wire, the semiconductor chip side was resin sealed with a commercial epoxy molding resin. Then after lightly contacting the 450 micron diameter eutectic solder balls with a rosin flux (made by Kyushu Matsushita electric, MSP 511), 64 solder balls were mounted per one package. After this, reflowing was conducted in a reflow furnace at a maximum temperature of 240° C. (before the semiconductor device was mounted on the printed wiring board).

The temperature cycle test was performed with semiconductor devices mounted on the center of a 5 cm square printed wiring board, at a temperature from −40° C. to 120° C., and at a one hour period with respective holding periods of 20 minutes. After 500 cycles, for each hundred cycles, this was taken out of the cycle furnace, and the electrical resistance measured to evaluate the reliability of the connections. The number of semiconductor devices used in the test was 20 for each of the working examples and comparative examples. If the electrical resistance increased above a certain level for even one of the 64 terminal connections of the respective semiconductor devices, this was judged to be defective.

The solder wettability of the copper ring and the solder ball mount all showed good wettability irrespective of electroplating or electroless plating, and wit or without the cutout. The copper ring had sufficient solder wetting for both the substitute plating and the electroless plating, and had the effect of reinforcing with respect to the solder ball.

Moreover, with the comparative examples 9 through 11 for the 5 μm ring width, the width of the copper ring was too narrow, so that the adhesion with the polyamide film was weak, and the copper ring peeled away and came off in the tape carrier manufacturing process. Hence assembly of the semiconductor device was not carried out.

Table 1 shows the results of the temperature cycle test in the working examples 1 through 6 and the comparative examples 1 through 8.

TABLE 1

| | | | | | Number of |
|---|---|---|---|---|---|
| | | Copper ring | | | temperature |
| | | width(μm) | Cutout | Plating | cycles * (time) |
| C. | Example 1 | 10 | no | electro | 2300 |
| C. | Example 2 | | | electroless | 1800 |
| W. | Example 1 | 10 | yes | electro | 2300 |
| W. | Example 2 | | | electroless | 2300 |
| C. | Example 3 | 20 | no | electro | 1900 |
| C. | Example 4 | | | electroless | 2100 |
| W. | Example 3 | 20 | yes | electro | 2300 |
| W. | Example 4 | | | electroless | 2300 |
| C. | Example 5 | 30 | no | electro | 1800 |
| C. | Example 6 | | | electroless | 2300 |
| W. | Example 5 | 30 | yes | electro | 2300 |
| W. | Example 6 | | | electroless | 2300 |
| C. | Example 7 | 0 | — | electro | 1000 |
| C. | Example 8 | | | electroless | 1000 |

*at the time when breakage started.

From the test results, the improvement result for the temperature cycle life by providing the copper ring and securing the solder ball with the copper ring, was increased for both the case where a cutout was provided in the copper ring (working examples) and the case where this was not provided (comparative examples). Moreover, in all of the cycles other than the comparative examples 7 and 8, a reliability of more than 1.8 times that for the comparative examples 7 and 8 was obtained. Furthermore, the affect did not changed for where the cutout was provided at one place or where the cutout was provided at two places, and similarly a stabilized life of more than 1.8 times was obtained.

With the copper ring width greater than 10 μm, a sufficient effect was obtained.

Both in the case where electroplating was applied or where electroless plating was applied, the temperature recycle test results were the same. From this it is seen that with the plating on the copper ring, if the wetting with the solder is good, even Au substituted plating is suitable, and a thickness of less than 0.05 μm is satisfactory.

For working example 9, a tape carrier for semiconductor device was made in the same way as for comparative example 1, except that the diameter of the copper rings was 450 μm.

Furthermore, with working examples 7 to 9, a tape carrier for semiconductor device was made in the same way as for working example 1, except that a cutout opening of 20 μm, 30 μm and 50 μm width was singly provided in the copper ring. The cutout opening of the copper ring was less than 4% of the circumferential length.

For comparison, a tape carrier for semiconductor device of comparative example 7 was made, with the cutout opening of the copper ring 60 μm wide, being greater than 4% of the circumferential length.

In all of the examples, a visual inspection was made of the shape of the formed solder ball, and as to whether the center of the solder ball is not displaced from the center of the via hole, that is, whether the solder ball is in a condition enabling accurate connection with the printed wiring board. The results are shown in Table 2.

TABLE 2

| | | | Ratio to | |
|---|---|---|---|---|
| | | Cutout opening | circumferential | Displacement of the |
| | | (μm) | length (%) | mounted solder ball |
| C. | Example 9 | 0 | 0.0 | no |
| W. | Example 7 | 20 | 1.4 | no |
| W. | Example 8 | 30 | 2.1 | no |
| W. | Example 9 | 50 | 3.5 | no |
| C. | Example 10 | 60 | 4.2 | yes |

With the tape carrier for semiconductor device of the present invention with the cutout opening less than 4%, there was no displacement of the mounting of the solder ball, enabling accurate connection with the printed wiring board.

For working examples 10, 11, 12 and 13, a tape carrier for semiconductor device was made in the same way as for working example 1, except that the diameter of the copper rings was 450 μm, and a plurality of gas removal paths with a total width of 4%, 20%, 30% or 40% of the circumferential length were provided at symmetrical positions.

For comparison, for comparative example 11, a tape carrier for semiconductor device was made the same as for working example 1, except that a plurality of gas removal paths with a total width of 50% of the circumferential length were provided at symmetrical positions.

Respective temperature cycle tests as mentioned above were then carried out. The results are shown in Table 3.

TABLE 3

| | | Total width of the gas | Number of temperature cycles |
|---|---|---|---|
| | | removal paths (%) | *(time) |
| W. | Example 10 | 4 | 2300 |
| W. | Example 11 | 20 | 2300 |
| W. | Example 12 | 30 | 1800 |
| W. | Example 13 | 40 | 1800 |
| C. | Example 11 | 50 | 1100 |

*when breakage started.

From Table 3 it can be seen that with a tape carrier for semiconductor device of the present invention where the total width of the gas removal paths is less than 40% of the circumferential length, the reinforcement effect of the solder ball due to the copper ring is obtained.

As described above, with the present invention, thermal stress related cracking occurring at the connection portions between the tape carrier and the solder balls in the semiconductor device, due the difference in coefficients of thermal expansion of the semiconductor device and the print wiring board is prevented, enabling connections with high reliability.

What is claimed is:

1. A tape carrier for a semiconductor device comprising a flexible insulation tape having via holes for a solder ball, a metal wiring layer formed on one surface of the insulation tape, the via halls for the solder balls having an opening on the other surface of the insulating tape, and a ring-shaped metal brace formed on the periphery of the opening of the respective via holes and provided with a cutout opening having a width up to 4% of the circumferential length of the periphery.

2. A tape carrier for a semiconductor device comprising a flexible insulation tape having via holes for a solder ball, a metal wiring layer formed on one surface of the insulation tape, the via halls for the solder balls having an opening on the other surface of the insulating tape, and a metal brace formed on the periphery of the opening of the respective via holes and comprising a plurality of arcuate shape portions, such that gaps are simetorically provided and positioned between the arcuate shape portions,, and that the total width of the gaps is up to 40% of the circumferential length of the periphery.

3. A tape carrier for a semiconductor device of one of claims 1 and 2, wherein the metal braces have a surface to which Ni plating is applied, and Au plating is applied to the Ni plating.

4. A tape carrier for a semiconductor device of one of claims 1 and 2, wherein the metal braces have a surface to which Au plating is applied.

5. A method for manufacturing a tape carrier for a semiconductor device comprising the steps of forming a metal foil on both surfaces of the flexible insulation tape, forming a metal wiring layer for mounting semiconductor chips on one face by forming a protective film and then etching and removing the protective film, exposing the insulation tape at desired positions on the other face, protecting one of the surfaces including the metal wiring layer by a protective film of resin, forming via holes by performing etching on the exposed portion of the insulation tape at the desired positions, forming a resin protective film on the via holes and part of the periphery of the via holes, and removing said metal foil at the portion exposed from the protective film by etching, wherein a width of the removed metal foil at the periphery of the opening of the via halls is up to 4% of the circumferential length of the periphery, and the remaining portion of the metal foil forms a ring-shaped metal brace, and then removing the protective film formed on both surfaces of the insulation tape.

6. A method for manufacturing a tape carrier for a semiconductor device comprising the steps of forming a metal foil on both surfaces of the flexible insulation tape, forming a metal wiring layer for mounting semiconductor chips on one face by forming a protective film and then etching and removing the protective film, exposing the insulation tape at desired positions on the other face, protecting one of the surfaces including the metal wiring layer by a protective film of resin, forming via holes by performing etching on the exposed portion of the insulation tape at the desired positions, forming a resin protective film on the via holes and a plurality of portions of the periphery of the via holes, and removing said metal foil at the portion exposed from the protective film by etching, such that the remaining portion of the metal foil forms a metal brace, and then removing the protective film formed on both surfaces of the insulation tape, whereby the metal brace comprises a plurality of arcuate shape portions, such that gaps are simetorically provided and positioned between the arcuate shape portions, and that the total width of the gaps is up to 40% of the circumferential length of the periphery.

7. A method of one of claims 5 and 6, wherein the metal braces have a surface to which Ni plating is applied, and Au plating is applied to the Ni plating.

8. A method of one of claims 5 and 6, wherein the metal braces have a surface to which Au plating is applied.

9. A semiconductor device using the tape carrier for the semiconductor device of one of claims 1 to 4, wherein semiconductor chips are connected to the metal wiring layer, and the solder balls are mounted so as to cover the via holes and the metal braces, such that the metal wiring layer is electrically connected to the solder balls.

10. A method of manufacturing a semiconductor device comprising the steps in one of claims 1 to 4, and further the steps of connecting semiconductor chips to the metal wiring layer, and mounting solder balls to cover the via holes and the metal braces, and electrically connected the metal wiring layer to the solder balls.

11. A tape carrier for a semiconductor device comprising a flexible insulation tape for mounting semiconductor chips and having via holes there through at desired locations, a metal wiring layer formed on one surface of the insulation tape and electrically connected to the semiconductor chips, solder balls formed on the other surface of the insulating tape and electrically connected to the metal wiring layer through the via halls, and a ring-shaped metal brace formed on the other surface of the insulation tape at a location of the respective solder balls in contact with the solder balls and provided with a cutout opening having a width up to 4% of the circumferential length of the periphery.

12. A tape carrier for a semiconductor device comprising a flexible insulation tape for mounting semiconductor chips and having via holes there through at desired locations, a metal wiring layer formed on one surface of the insulation tape and electrically connected to the semiconductor chips, solder balls formed on the other surface of the insulating tape and electrically connected to the metal wiring layer through the via halls, and a metal brace formed on the other surface of the insulation tape at a location of the respective solder balls in contact with the solder balls and comprising a plurality of arcuate shape portions, such that gaps are simetorically provided and positioned between the arcuate shape portions, and that the total width of the gaps is up to 40% of the circumferential length of the periphery.
